(19) United States
(12) Patent Application Publication
(10) Pub. No.: US 2023/0213859 A1
(43) Pub. Date: Jul. 6, 2023

(54) POSITIVE-TYPE PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Yeonok KIM, Gyeonggi-do (KR); Jin Kyu IM, Gyeonggi-do (KR); Ju-Young JUNG, Gyeonggi-do (KR)

(21) Appl. No.: 18/075,351

(22) Filed: Dec. 5, 2022

(30) Foreign Application Priority Data
Dec. 30, 2021 (KR) 10-2021-0193109

(51) Int. Cl. G03F 7/039; G03F 7/38

(52) U.S. Cl. CPC G03F 7/039; G03F 7/38

(57) ABSTRACT

The present invention relates to a positive-type photosensitive resin composition and a cured film prepared therefrom. As the positive-type photosensitive resin composition comprises a siloxane copolymer having a bridge structure introduced into its molecule, it is possible to form a cured film with an excellent film retention rate and improved surface cloudiness phenomenon after development.

### TECHNICAL FIELD

The present invention relates to a positive-type photosensitive resin composition and to a cured film prepared therefrom. Specifically, the present invention relates to a positive-type photosensitive resin composition capable of forming a cured film (insulation film) having improved surface cloudiness while having an excellent film retention rate.

### BACKGROUND ART

Positive-type photosensitive resin compositions capable of forming a specific pattern through relatively fewer steps are used for preparing a cured film (insulation film) to be adopted in a liquid crystal display device, an organic EL display device, and the like.

Examples of the positive-type photosensitive resin composition include a photosensitive resin composition containing an acrylic resin and a photoactive agent (PAC) as raw materials. Such a photosensitive resin composition can form a cured film that is excellent in chemical resistance by virtue of the crosslinking characteristics of acryl. However, a cured film formed from a photosensitive resin composition comprising an acrylic resin has a problem in that the film retention rate is low and that the bonding strength to a substrate is weak, so that its adhesion is poor.

In order to solve the above problems, a positive-type photosensitive resin composition comprising a siloxane copolymer as a raw material together with an acrylic resin has been proposed (see Patent Document 1). Since the siloxane copolymer contains a silanol group and has a relatively fast dissolution rate in a developer, the sensitivity, film retention rate, adhesion, and the like of a cured film formed from a photosensitive resin composition comprising the siloxane copolymer can be improved. However, a cured film formed from a photosensitive resin composition comprising a siloxane copolymer has a limit in achieving a required level of film retention rate due to residual unreacted silanol groups originating from the siloxane copolymer. In addition, there has been a problem in that the surface of a cured film upon development is cloudy due to the addition reaction of the unreacted silanol groups.

### PRIOR ART DOCUMENT

(Patent Document 1) Korean Laid-open Patent Publication No. 2010-0043259

### DISCLOSURE OF INVENTION

### Technical Problem

In order to solve the above-mentioned problems in the art, the present inventors have conducted various studies. As a result, it has been discovered that a cured film having an excellent film retention rate and improved surface cloudiness can be obtained by controlling the dissolution rate of a pre-baked film by using a siloxane copolymer having a specific structure.

Accordingly, the present invention aims to provide a positive-type photosensitive resin composition having improved physical properties and a cured film prepared therefrom and having excellent sensitivity and film retention rate and minimized surface cloudiness.

### Solution to Problem

In order to accomplish the above object, the present invention provides a positive-type photosensitive resin composition, which comprises (A) a siloxane copolymer; (B) a 1,2-quinonediazide compound; and (C) a solvent, wherein when the siloxane copolymer (A) is pre-baked, the dissolution rate in an aqueous solution of 1.5% by weight of tetramethylammonium hydroxide is 2,500 Å/second or more, and when a mixture in which the siloxane copolymer (A) and the 1,2-quinonediazide compound (B) are mixed at a content of the 1,2-quinonediazide compound (B) of 15% by weight is pre-baked, it is insoluble in an aqueous solution of 1.5% by weight of tetramethylammonium hydroxide.

In addition, the present invention provides a positive-type photosensitive resin composition, which comprises (A) a siloxane copolymer; (B) a 1,2-quinonediazide compound; (C) a solvent, wherein the siloxane copolymer (A) comprises a structural unit (a-1) derived from a silane compound (a₁) represented by the following Formula 1 or 2:

(R¹O)₃Si-L-Si(OR²)₃ [Formula 1]

R³Si(OR⁴)₃ [Formula 2]

in Formulae 1 and 2,

L is a single bond, oxygen, a substituted or unsubstituted C₁ to C₁₅ alkylene group, a substituted or unsubstituted C₃ to C₁₅ cycloalkylene group, a substituted or unsubstituted C₆ to C₁₅ arylene group, a substituted or unsubstituted 6- to 15-membered heteroarylene group, a substituted or unsubstituted C₂ to C₁₅ alkenylene group, or a substituted or unsubstituted C₂ to C₁₅ alkynylene group,

R¹, R², and R⁴ are each independently a substituted or unsubstituted C₁ to C₆ alkyl group, a substituted or unsubstituted Cₜ to C₆ acyl group, or a substituted or unsubstituted C₆ to C₁₅ aryl group,

R³ is a C₁ to C₆ alkyl group substituted with a C₂ to C₁₅ cyclic ether group, and

the heteroarylene group has one or more heteroatoms selected from the group consisting of N, O, and S.

In addition, the present invention provides a cured film formed from the positive-type photosensitive resin composition.

### Advantageous Effects of Invention

Since the positive-type photosensitive resin composition according to the present invention comprises a siloxane copolymer having a bridge structure introduced into its molecule, it is possible to increase the film retention rate of a cured film (a cured film after exposure and development before post-bake) while preventing the surface cloudiness phenomenon of the cured film.

Accordingly, the positive-type photosensitive resin composition according to the present invention can be advantageously used for forming a planarization film for a thin film transistor (TFT) substrate of a liquid crystal display or an organic EL display, a partition of an organic EL display, an interlayer dielectric of a semiconductor device, and the like.

### BEST MODE FOR CARRYING OUT THE INVENTION

Hereinafter, the present invention will be described in detail. However, the present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein may be understood as being modified by the term “about” unless specifically stated otherwise.

Positive-Type Photosensitive Resin Composition

The present invention relates to a positive-type photosensitive resin composition (hereinafter, to be optionally referred to as “photosensitive resin composition”). The photosensitive resin composition comprises (A) a siloxane copolymer; (B) a 1,2-quinonediazide compound; and (C) a solvent, which is explained in detail, as follows. Hereinafter, the term “(meth)acryl” refers to “acryl” and/or “methacryl,” and the term “(meth)acrylate” described below may refer to “acrylate” and/or “methacrylate.”

(A) Siloxane Copolymer

The photosensitive resin composition according to the present invention comprises a siloxane copolymer (or polysiloxane) (A).

The siloxane copolymer (A), when pre-baked, may have a dissolution rate of 2,500 Å/second or more, specifically, 2,500 to 4,000 Å/second, more specifically, 2,700 to 3,500 Å/second, in an aqueous solution of 1.5% by weight of tetramethylammonium hydroxide. In addition, when the siloxane copolymer (A) is mixed with a 1,2-quinonediazide compound (B) to be described below, and when a mixture (A+B) in which they are mixed at a content of the 1,2-quinonediazide compound (B) of 15% by weight (i.e., 85% by weight of the siloxane copolymer (A) and 15% by weight of the 1,2-quinonediazide compound (B)) is pre-baked, it may be insoluble in an aqueous solution of 1.5% by weight of tetramethylammonium hydroxide.

As the dissolution rate of a pre-baked film of the siloxane copolymer (A) in an aqueous solution of 1.5% by weight of tetramethylammonium hydroxide is within the above range, and as a pre-baked film of a mixture (A+B) comprising the 1,2-quinonediazide compound (B) in an amount of 15% by weight is insoluble in an aqueous solution of 1.5% by weight of tetramethylammonium hydroxide, the reaction between the silanol group contained (or present) in the siloxane copolymer (A) and the 1,2-quinonediazide compound (B) is well carried out, thereby increasing the inhibition efficiency of the reactivity of the silanol group contained in the siloxane copolymer (A). As a result, as the developability of a cured film is improved, a cured film having enhanced film retention rate, sensitivity, and resolution characteristics may be formed.

The siloxane copolymer (A) may comprise a structural unit derived from a silane compound. That is, the siloxane copolymer (A) may be a hydrolysate of a silane compound or a condensate thereof.

Specifically, the siloxane copolymer (A) may comprise a structural unit (a-1) derived from a silane compound (a₁) represented by the following Formula 1 or 2.

(R¹O)₃Si-L-Si(OR²)₃ [Formula 1]

R³Si(OR⁴)₃ [Formula 2]

in Formulae 1 and 2,

L is a single bond, oxygen, a substituted or unsubstituted C₁ to C₁₅ alkylene group, a substituted or unsubstituted C₃ to C₁₅ cycloalkylene group, a substituted or unsubstituted C₆ to C₁₅ arylene group, a substituted or unsubstituted 6- to 15-membered heteroarylene group, a substituted or unsubstituted C₂ to C₁₅ alkenylene group, or a substituted or unsubstituted C₂ to C₁₅ alkynylene group, R¹, R², and R⁴ are each independently a substituted or unsubstituted C₁ to C₆ alkyl group, a substituted or unsubstituted C₁ to C₆ acyl group, or a substituted or unsubstituted C₆ to C₁₅ aryl group, R³ is a C₁ to C₆ alkyl group substituted with a C₂ to C₁₅ cyclic ether group, and the heteroarylene group has one or more heteroatoms selected from the group consisting of N, O, and S.

In Formulae 1 and 2, when the alkylene group, the cycloalkylene group, the arylene group, the heteroarylene group, the alkenylene group, and the alkynylene group of L and the alkyl group, the acyl group, and the aryl group of R¹, R², and R⁴ are substituted, the substituents bonded to these functional groups are each independently at least one selected from the group consisting of a halogen group (F, Br, Cl, or I), a hydroxyl group, a nitro group, a cyano group, an amino group, a carbonyl group, a thiol group, a carboxyl group, a C₁ to C₁₅ alkyl group, a C₂ to C₁₅ alkenyl group, a C₂ to C₁₅ alkynyl group, a C₆ to C₁₅ aryl group, a 6- to 15-membered heteroaryl group, a C₁ to C₁₅ alkoxy group, and a C₃ to C₁₅ cycloalkyl group.

Specifically, when the reactivity inhibition efficiency of the silanol group contained in the siloxane copolymer (A) is taken into account, in Formulae 1 and 2, L may be a C₂ to C₆ alkylene group, and R¹, R², and R⁴ may each independently be a C₁ to C₄ alkyl group, and R³ may be a C₁ to C₄ alkyl group substituted with a C₄ to C₈ cyclic ether group.

In addition, the cyclic ether group substituted to the alkyl group of R³ may be an epoxy group or a C₃ to C₁₀ cycloalkyl group containing an epoxy structure.

The silane compound (a₁) may be specifically selected from the group consisting of compounds represented by the following Formulae 4 to 6.

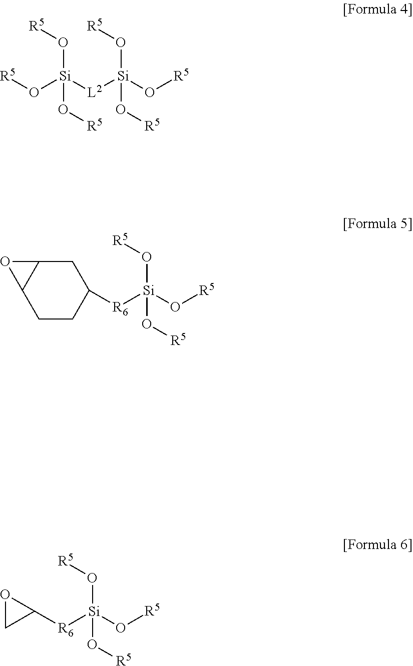

In Formulae 4 to 6, L² is a C₂ to C₆ alkylene group, R⁵ is each independently a C₁ to C₄ alkyl group, and R⁶ is a C₁ to C₄ alkylene group.

As the structural unit (a-1) derived from the silane compound (a₁) is contained in the siloxane copolymer (A), a bridge structure is introduced into the molecule of the siloxane copolymer (A), which facilitates the bonding with a 1,2-quinonediazide compound (B) as a photoactive agent. As a result, a cured film having enhanced film retention rate, sensitivity, resolution, and the like may be formed.

That is, conventionally, the steric hindrance of a siloxane copolymer impairs the smooth bonding between the silanol group contained in the siloxane copolymer and a 1,2-quinonediazide compound, thereby deteriorating the efficiency of suppressing the reactivity of the silanol group. This has acted as a factor of excessively increasing the developability of a cured film, thereby decreasing the film retention rate. In addition, if the silanol group contained in a siloxane copolymer is not bonded with a 1,2-quinonediazide compound and remains unreacted (i.e., free silanol is present), an addition reaction (e.g., a reaction between a silanol group and an epoxy group contained in an acrylic copolymer) takes place, which causes cloudiness on the surface of a cured film upon development.

However, as the siloxane copolymer (A) according to the present invention comprises the structural unit (a-1) derived from the silane compound (a₁), a bridge structure is introduced into the molecule of the siloxane copolymer (A), which improves the steric hindrance of the siloxane copolymer. As a result, a bond between the silanol group and the 1,2-quinonediazide compound is smoothly achieved, which may increase the efficiency of suppressing the undesired reactivity of the silanol group. As the efficiency of suppressing the undesired reactivity of a silanol group is increased, it is possible in the present invention to appropriately control the developability of a cured film to secure the film retention rate at a required level and to prevent cloudiness on the surface of the cured film upon development.

Here, examples of the structural unit (a-1) constituting the siloxane copolymer (A) to which a bridge structure has been introduced include a structural unit represented by the following Formula 7 or 8.

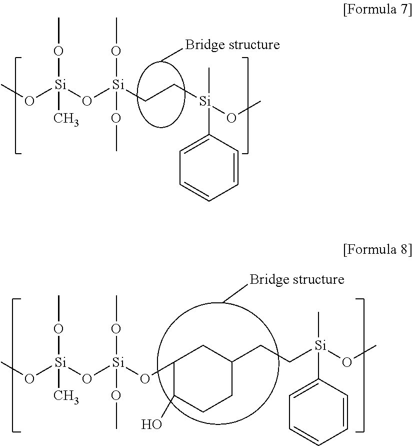

This siloxane copolymer (A) comprises the structural unit (a-1) derived from the silane compound (a₁) in an amount of 1 to 50% by mole, 1 to 45% by mole, 1 to 40% by mole, or 1 to 35% by mole, based on the number of moles of Si atoms contained in the total structural units constituting the siloxane copolymer (A)(i.e., based on 100% by mole of the structural units constituting the siloxane copolymer (A)). If the content of the structural unit (a-1) is within the above range, it is possible to secure the film retention rate, sensitivity, and resolution of a cured film at a required level.

In addition, the siloxane copolymer (A) may comprise a phenyl group in its molecule. Specifically, the siloxane copolymer (A) may comprise a phenyl group in an amount of 10 to 60% by mole relative to the number of moles of Si atoms contained in the total structural units constituting the siloxane copolymer (A). If the content of a phenyl group is within the above range, the compatibility with a 1,2-quinonediazide compound (B) may be excellent.

Meanwhile, the siloxane copolymer (A) may further comprise a structural unit (a-2) derived from a silane compound (a₂) represented by the following Formula 3. Specifically, the siloxane copolymer (A) may comprise a structural unit (a-2′) derived from three or more types of silane compounds represented by the following Formula 3.

(R⁷)ₙSi(OR⁸)₄₋ₙ [Formula 3]

in Formula 3,

n is an integer of 0 to 3,

R⁷ is each independently C₁ to C₁₂ alkyl, C₂ to C₁₀ alkenyl, C₆ to C₁₅ aryl, 3- to 12-membered heteroalkyl, 4- to 10-membered heteroalkenyl, or 6- to 15-membered heteroaryl,

R⁸ is each independently hydrogen, C₁ to C₆ alkyl, C₂ to C₆ acyl, or C₆ to C₁₅ aryl, and

the heteroalkyl, the heteroalkenyl, and the heteroaryl groups each independently have at least one heteroatom selected from the group consisting of O, N, and S.

In Formula 3, the compound may be a tetrafunctional silane compound where n is 0, a trifunctional silane compound where n is 1, a difunctional silane compound where n is 2, or a monofunctional silane compound where n is 3. As a result, the siloxane copolymer (A) may comprise at least one type of siloxane structural units selected from the following Q, T, D, and M types:
Q type siloxane structural unit (n=0): a siloxane structural unit comprising a silicon atom and four adjacent oxygen atoms, which may be derived from, for example, a tetrafunctional silane compound or a hydrolysate of a silane compound that has four hydrolyzable groups.
T type siloxane structural unit (n=1): a siloxane structural unit comprising a silicon atom and three adjacent oxygen atoms, which may be derived from, for example, a trifunctional silane compound or a hydrolysate of a silane compound that has three hydrolyzable groups.
D type siloxane structural unit (n=2): a siloxane structural unit comprising a silicon atom and two adjacent oxygen atoms (i.e., a linear siloxane structural unit), which may be derived from, for example, a difunctional silane compound or a hydrolysate of a silane compound that has two hydrolyzable groups.
M type siloxane structural unit (n=3): a siloxane structural unit comprising a silicon atom and one adjacent oxygen atom, which may be derived from, for example, a monofunctional silane compound or a hydrolysate of a silane compound that has one hydrolyzable group.

Particular examples of the silane compound (a₂) represented by Formula 3 may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifunctional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d3-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; and preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

Conditions for preparing the siloxane copolymer (A) through the silane compounds (a₁, a₂) are not particularly limited. Specifically, the silane compounds (a₁, a₂) are optionally diluted with a solvent, and water and an acid catalyst (e.g., hydrochloric acid, acetic acid, nitric acid, or the like) or a base catalyst (e.g., ammonia, triethylamine, cyclohexylamine, tetramethylammonium hydroxide, or the like) are added thereto, followed by a hydrolysis polymerization reaction to obtain the desired siloxane copolymer (A) as a hydrolysate or a condensate thereof.

The types and amounts of the solvent, acid catalyst, and base catalyst are not particularly limited.

The hydrolysis polymerization reaction may be carried out at a low temperature of 20° C. or lower. Alternatively, the reaction may be expedited by heating or refluxing. In addition, the time for the hydrolysis polymerization reaction may be appropriately adjusted according to the type and concentration of the silane compound, the reaction temperature, and the like.

Meanwhile, when the siloxane copolymer (A) comprises a siloxane structural unit of D-type, its content may be 0 to 30% by mole. Specifically, the siloxane copolymer (A) may comprise the structural unit of D-type derived from a silane compound of Formula 3 where n is 2 in an amount of 0 to 25% by mole, preferably 1 to 20% by mole, more preferably 1 to 15% by mole, based on the number of moles of Si atoms contained in the total structural units constituting the siloxane copolymer (A). Within the above content range, a cured film with good pattern formation can be obtained.

When the siloxane copolymer (A) comprises a siloxane structural unit of T-type, its content may be 10 to 95% by mole. Specifically, the siloxane copolymer (A) may comprise the structural unit of T-type derived from a silane compound of Formula 3 where n is 1 in an amount of 20 to 90% by mole, preferably 30 to 85% by mole, more preferably 40 to 80% by mole, based on the number of moles of Si atoms contained in the total structural units constituting the siloxane copolymer (A). Within the above content range, it is possible to increase the precision of the pattern formed on a cured film while achieving the required hardness.

When the siloxane copolymer (A) comprises a siloxane structural unit of Q-type, its content may be 5 to 60% by mole. Specifically, the siloxane copolymer (A) may comprise the structural unit of Q-type derived from a silane compound of Formula 3 where n is 0 in an amount of 10 to 55% by mole, preferably 15 to 50% by mole, more preferably 20 to 45% by mole, based on the number of moles of Si atoms contained in the total structural units constituting the siloxane copolymer (A). Within the above content range, the sensitivity and developability of a cured film can be enhanced.

The siloxane copolymer (A) may comprise a siloxane structural unit of T-phenyl type derived from a silane compound having an aryl group (a silane compound of Formula 3 in which n=1, and R⁷ is a phenyl group) in view of the hardness, sensitivity, and film retention rate of a cured film. Specifically, the siloxane copolymer (A) may comprise the structural unit derived from a silane compound having an aryl group in an amount of 10 to 60% by mole, preferably 15 to 55% by mole, more preferably 20 to 50% by mole, based on the number of moles of Si atoms contained in the total structural units constituting the siloxane copolymer (A). Within the above content range, the compatibility of the siloxane copolymer (A) with a 1,2-naphthoquinonediazide compound is excellent, which may prevent an excessive decrease in sensitivity of a cured film while enhancing the transparency of the cured film.

The siloxane copolymer (A) may be composed of a siloxane copolymer (A1) alone, which comprises a structural unit (a-1) derived from the silane compound (a₁) represented by Formula 1 or 2 and a structural unit (a-2) derived from the silane compound (a₂) represented by Formula 3, or it may be a mixture of the siloxane copolymer (A1) and a siloxane copolymer (A2) comprising a structural unit (a-2) derived from the silane compound (a₂) represented by Formula 3.

The mixing ratio (A1:A2) of the siloxane copolymer (A1) and the siloxane copolymer (A2) is not particularly limited, but it may be a weight ratio of 1:99 to 30.70.

The term “% by mole relative to the number of moles of Si atoms” as used herein may refer to a percentage of the number of moles of Si atoms contained in a specific structural unit with respect to the total number of moles of Si atoms contained in all of the structural units constituting the siloxane polymer (A).

The molar content (% by mole) of a siloxane structural unit contained in the siloxane copolymer (A) may be measured by the combination of Si-NMR, ¹H-NMR, ¹³C-NMR, IR, TOF-MS, elementary analysis, measurement of ash, and the like. For example, in order to measure the molar content of a siloxane structural unit having a phenyl group, an Si-NMR analysis is performed on the entire siloxane copolymer, followed by an analysis of the phenyl-bound Si peak area and the phenyl-unbound Si peak area. The molar amount can then be computed from the peak area ratio between them.

The weight average molecular weight of the siloxane copolymer (A) may be 100 to 50,000, 1,000 to 45,000, 1,500 to 40,000, 2,000 to 30,000, 3,000 to 20,000, or 5,000 to 15,000. If the weight average molecular weight is within the above range, the sensitivity of a cured film and its dissolution rate to a developer may be excellent.

The amount of the siloxane copolymer (A) may be 10% by weight to 95% by weight, 15% by weight to 90% by weight, 20% by weight to 85% by weight, or 25% by weight to 80% by weight, based on the total weight (solids content) of the photosensitive resin composition excluding the balanced amount of solvents. Within the above content range, the developability is appropriately controlled, which can enhance the film retention rate and pattern resolution of a cured film.

(B) 1,2-Quinonediazide Compound

The photosensitive resin composition according to the present invention comprises a 1,2-quinonediazide compound (B) as a photoactive agent.

Specific examples of the 1,2-quinonediazide compound (B) may include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which the hydroxyl group is substituted with an amino group and 1,2-benzoquinonediazide-4-sulfonic acid or 1,2-benzoquinonediazide-5-sulfonic acid; a sulfonamide of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

The phenolic compound may specifically be 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, or 2,2,4-trimethyl-7,2′,4′-trihydroxyflavane.

Such a 1,2-quinonediazide compound (B) may specifically be an ester of 2,3,4-trihydroxybenzophenone and 1,2-naphthoquinonediazide-4-sulfonic acid; an ester of 2,3,4-trihydroxybenzophenone and 1,2-naphthoquinonediazide-5-sulfonic acid; an ester of 4,4′-[1-[4-[1-[4-hydroxyphenyl]-1-methylethyl]phenyl]ethylidene]bisphenol and 1,2-naphthoquinonediazide-4-sulfonic acid; or an ester of 4,4′-[1-[4-[1-[4-hydroxyphenyl]-1-methylethyl]phenyl]ethylidene]bisphenol and 1,2-naphthoquinonediazide-5-sulfonic acid. The above compounds may be used alone or in combination of two or more thereof.

The content of the 1,2-quinonediazide compound (B) may be 5 to 100 parts by weight, 5.5 to 90 parts by weight, 7 to 80 parts by weight, 10 to 70 parts by weight, 11 to 60 parts by weight, or 13 to 50 parts by weight, relative to 100 parts by weight of the siloxane copolymer (A) on the basis of solids content. Within the above content range, a pattern is more readily formed, and it is possible to prevent such defects as a rough surface of a cured film upon the formation thereof and such a pattern shape as scum appearing at the bottom portion upon development.

(C) Solvent

The photosensitive resin composition according to the present invention comprises a solvent (C). The solvent (C) serves to dissolve or disperse each component contained in the photosensitive resin composition.

Specifically, the solvent (C) may be an organic solvent such as alcohols, ethers, glycol ethers, ethylene glycol alkyl ether acetates, diethylene glycol, propylene glycol monoalkyl ethers, propylene glycol alkyl ether acetates, propylene glycol alkyl ether propionates, aromatic hydrocarbons, ketones, or esters.

More specifically, the solvent (C) may be methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol monomethyl ether acetate, propylene glycol monoethyl ether acetate, propylene glycol monopropyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, or N-methylpyrrolidone. The above compounds may be used alone or in combination of two or more thereof.

Preferred as the solvent (C) among the above may be diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol monomethyl ether acetate, methyl 2-methoxypropionate, γ-butyrolactone, or 4-hydroxy-4-methyl-2-pentanone.

The content of the solvent (C) may be the balance excluding the contents of the respective components contained in the photosensitive resin composition. Specifically, the content of the solvent (C) may be adjusted such that the solids content is 10 to 90% by weight, 15 to 85% by weight, 30 to 85% by weight, or 50 to 80% by weight, based on the total weight of the photosensitive resin composition.

(D) Acrylic Copolymer

The photosensitive resin composition according to the present invention may further comprise an acrylic copolymer (D). The acrylic copolymer (D) may serve as an alkali-soluble resin for achieving developability in the development step, thereby increasing the developability. In addition, it may play the role of a base for forming a cured film upon coating and a structure for forming a final pattern.

The acrylic copolymer (D) may comprise (D-1) a structural unit derived from an ethylenically unsaturated carboxylic acid, an ethylenically unsaturated carboxylic anhydride, or a combination thereof; (D-2) a structural unit derived from an unsaturated compound containing an epoxy group; and (D-3) a structural unit derived from an ethylenically unsaturated compound different from the structural units (D-1) and (D-2).

(D-1) Structural Unit Derived from an Ethylenically Unsaturated Carboxylic Acid, an Ethylenically Unsaturated Carboxylic Anhydride, or a Combination Thereof.

The structural unit (D-1) is derived from an ethylenically unsaturated carboxylic acid, an ethylenically unsaturated carboxylic anhydride, or a combination thereof. The ethylenically unsaturated carboxylic acid and the ethylenically unsaturated carboxylic anhydride may be a polymerizable unsaturated compound containing at least one carboxyl group in the molecule.

Specifically, the ethylenically unsaturated carboxylic acid, the ethylenically unsaturated carboxylic anhydride, or a combination thereof may be at least one selected from the group consisting of an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof, and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate. (Meth)acrylic acid among the above may be preferable from the viewpoint of developability.

The amount of the structural unit (D-1) may be 5 to 50% by mole, preferably 10 to 40% by mole, based on the total moles of the structural units constituting the acrylic copolymer (D). Within the above content range, it is possible to attain a pattern of a cured film with good developability.

(D-2) Structural Unit Derived from an Unsaturated Compound Containing an Epoxy Group

The structural unit (D-2) is derived from an unsaturated monomer containing at least one epoxy group. The unsaturated monomer containing at least one epoxy group may be at least one selected from the group consisting of glycidyl (meth)acrylate, 4-hydroxybutyl acrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, and 2-methylallyl glycidyl ether. Glycidyl (meth)acrylate, 3,4-epoxycyclohexyl (meth)acrylate, 4-hydroxybutyl acrylate glycidyl ether, or a mixture thereof may be preferable from the viewpoint of storage stability at room temperature and solubility.

The amount of the structural unit (D-1) may be 1 to 45% by mole, preferably 3 to 30% by mole, based on the total moles of the structural units constituting the acrylic copolymer (D). Within the above content range, the storage stability of the photosensitive resin composition may be maintained, and the film retention rate may be enhanced upon post-bake.

(D-3) Structural Unit Derived from an Ethylenically Unsaturated Compound Different from the Structural Units (D-1) and (D-2)

The structural unit (D-3) is derived from an ethylenically unsaturated compound different from the structural units (D-1) and (D-2). The ethylenically unsaturated compound different from the structural units (D-1) and (D-2) may be specifically at least one selected from the group consisting of an ethylenically unsaturated compound having an aromatic ring including phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, acetyistyrene, vinyl toluene, divinylbenzene, vinylphenol, o-vinylbenzyl methyl ether, m-vinylbenzyl methyl ether, or p-vinylbenzyl methyl ether; an unsaturated carboxylic acid ester including methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, dicyclopentenyloxyethyl (meth)acrylate, glycidyl (meth)acrylate, 3,4-epoxybutyl (meth)acrylate, 4,5-epoxypentyl (meth)acrylate, 5,6-epoxyhexyl (meth)acrylate, or 6,7-epoxyheptyl (meth)acrylate; an N-vinyl tertiary amine containing an N-vinyl group including N-vinyl pyrrolidone, N-vinyl carbazole, or N-vinyl morpholine; an unsaturated ether including vinyl methyl ether or vinyl ethyl ether; and an unsaturated imide including N-phenylmaleimide, N-(4-chlorophenyl)maleimide, N-(4-hydroxyphenyl)maleimide, or N-cyclohexylmaleimide.

The amount of the structural unit (D-3) may be 5 to 70% by mole, preferably 15 to 65% by mole, based on the total moles of the structural units constituting the acrylic copolymer (D). Within the above content range, it is possible to control the reactivity of the acrylic copolymer (D) and to increase the solubility thereof in an aqueous alkaline solution, so that the coatability of the photosensitive resin composition can be remarkably enhanced.

The acrylic copolymer (D) may be prepared by compounding each of the compounds that provide the structural units (D-1), (D-2), and (D-3), and adding thereto a molecular weight controlling agent, a polymerization initiator, a solvent, and the like, followed by charging nitrogen thereto and slowly stirring the mixture for carrying out the polymerization.

The molecular weight controlling agent may be a mercaptan compound such as butyl mercaptan, octyl mercaptan, lauryl mercaptan, or the like, or an α-methylstyrene dimer, but it is not particularly limited thereto.

The polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide; lauryl peroxide; t-butyl peroxypivalate; 1,1-bis(t-butylperoxy)cyclohexane, or the like, but it is not limited thereto. The polymerization initiator may be used alone or in combination of two or more thereof.

The solvent may be any solvent commonly used in the preparation of an acrylic copolymer (D). It may preferably be methyl 3-methoxypropionate or propylene glycol monomethyl ether acetate.

The reaction conditions and the reaction time at the time of preparation of the acrylic copolymer (D) are not particularly limited. For example, the reaction temperature may be adjusted to a temperature lower than the conventional temperature, for example, from room temperature to 65° C. (or from room temperature to 60° C.). Then, the reaction time is to be preferably maintained until a sufficient reaction is carried out.

It is possible to control the residual amount of unreacted monomers in the acrylic copolymer (D) to a very minute level when the acrylic copolymer (D) is prepared by the above process. The unreacted monomers (or residual monomers) may refer to monomers that were supposed to provide the structural units (D-1) to (D-3) of the acrylic copolymer (D), but have not participated in the polymerization reaction (i.e., do not form a chain of the copolymer).

The acrylic copolymer (D) comprising the structural units (D-1) to (D-3) may be employed in the photosensitive resin composition as the acrylic copolymer (D) alone or a mixture of one or more acrylic copolymers (D).

The weight average molecular weight of the acrylic copolymer (D) may be 500 to 50,000, 1,000 to 30,000, 3,000 to 25,000, 5,000 to 15,000, or 6,000 to 12,000. If the weight average molecular weight is within the above range, adhesion to a substrate may be excellent, along with an appropriate viscosity.

The content of the acrylic copolymer (D) may be 1 to 900 parts by weight, 10 to 750 parts by weight, 50 to 600 parts by weight, 80 to 400 parts by weight, 100 to 300 parts by weight, or 200 to 250 parts by weight, relative to 100 parts by weight of the siloxane copolymer (A) on the basis of solids content. Within the above content range, the developability is appropriately controlled, so that the film retention rate and surface characteristics may be excellent.

(E) Epoxy Compound

The photosensitive resin composition according to the present invention may further comprise an epoxy compound (E). The epoxy compound (E) acts to increase the internal density of the siloxane copolymer (A), which may enhance the chemical resistance of a cured film. The epoxy compound (E) may be a homo-oligomer or a hetero-oligomer of an unsaturated monomer containing at least one epoxy group.

The unsaturated monomer containing at least one epoxy group may specifically be glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, glycidyl methacrylate or 3,4-epoxycyclohexyl (meth)acrylate may be used.

The epoxy compound (E) may be synthesized by any methods commonly known in the art.

The epoxy compound (E) may further comprise the following structural unit.

Specifically, the additional structural unit may be a structural unit derived from a compound such as styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; p-hydroxy-α-methylstyrene; acetylstyrene; an ethylenically unsaturated compound containing an aromatic ring such as divinylbenzene, vinylphenol, o-vinylbenzyl methyl ether, m-vinylbenzyl methyl ether, p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl a-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxydiethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like.

The additional structural unit derived from the above compounds may be contained in the epoxy compound (E) alone or in combination of two or more thereof. An additional structural unit derived from the styrene compounds among the above is preferred from the viewpoint of polymerizability.

Meanwhile, it may be preferable from the viewpoint of chemical resistance of a cured film that the epoxy compound (E) does not contain a structural unit derived from a compound having a carboxyl group among the above compounds.

The epoxy compound (E) may comprise the additional structural unit in an amount of 0 to 70% by mole, preferably 10 to 60% by mole, based on the total number of moles of the structural units constituting the epoxy compound (E). If the content is within the above range, it is possible to secure the hardness of a cured film at a required level.

The weight average molecular weight of the epoxy compound (E) may be 100 to 30,000, 500 to 25,000, 1,000 to 20,000, 2,000 to 15,000, 2,500 to 13,000, or 3,000 to 11,000. If the weight average molecular weight is within the above range, a cured film may have high hardness with a uniform thickness, which may be suitable for planarizing any steps.

The content of the epoxy compound (E) may be 1 to 60 parts by weight, 3 to 50 parts by weight, 5 to 40 parts by weight, 7 to 30 parts by weight, 9 to 20 parts by weight, or 10 to 15 parts by weight, relative to 100 parts by weight of the siloxane copolymer (A) on the basis of solids content. If the content is within the above range, the chemical resistance and adhesion of a cured film may be enhanced.

(F) Surfactant

The photosensitive resin composition according to the present invention may further comprise a surfactant (F). The surfactant (F) serves to enhance the coatability of the photosensitive resin composition and may be fluorine-based surfactants, silicon-based surfactants, or non-ionic surfactants.

The surfactant (F) may specifically be fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141, S-145, S-382, SC-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; or organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.). The above compounds may be used alone or in combination of two or more thereof.

The content of the surfactant (F) may be 0.001 to 5 parts by weight, 0.005 to 4 parts by weight, 0.01 to 3 parts by weight, 0.1 to 2.5 parts by weight, 0.5 to 2 parts by weight, or 1 to 1.5 parts by weight, relative to 100 parts by weight of the siloxane copolymer (A) on the basis of solids content. If the content is within the above range, the photosensitive resin composition may have excellent coatability.

The photosensitive resin composition according to the present invention may further comprise commonly known adhesion aids, defoamers, viscosity modifiers, dispersants, or the like within the range that does not affect the physical properties thereof

Cured Film

The present invention provides a cured film formed from the photosensitive resin composition described above.

The cured film according to the present invention may be formed by a method commonly known, for example, a method in which the photosensitive resin composition is coated on a substrate and then cured. Specifically, the photosensitive resin composition is coated on a substrate and subjected to pre-bake at a temperature of 60 to 130° C. to remove solvents; then exposed to light using a photomask having a desired pattern; and subjected to development using a developer (for example, a tetramethylammonium hydroxide (TMAH) solution) to form a pre-baked film having a pattern formed thereon. Thereafter, if necessary, the pre-baked film having a pattern is subjected to post-bake at a temperature of 150 to 300° C. for 10 minutes to 5 hours to prepare a desired cured film.

The exposure to light may be carried out at an exposure dose of 10 to 200 mJ/cm² based on a wavelength of 365 nm in a wavelength band of 200 to 500 nm. In addition, as a light source used for the exposure, a low-pressure mercury lamp, a high-pressure mercury lamp, an extra high-pressure mercury lamp, a metal halide lamp, an argon gas laser, or the like may be used. X-rays, electronic rays, or the like may also be used, if desired.

The method of coating the photosensitive resin composition onto a substrate may be a spin coating, a slit coating, a roll coating, a screen printing, an applicator, or the like. A cured film (coating film) in a desired thickness of, for example, 2 to 25 μm may be prepared by this method.

Since the present invention prepares (forms) a cured film from the photosensitive resin composition described above, it is possible to provide a cured film having excellent thermal resistance, transparency, dielectric constant, solvent resistance, acid resistance, and alkali resistance, along with a high film retention rate and improved surface cloudiness.

Accordingly, the cured film according to the present invention can be advantageously applied to such fields as electricity, electronics, or optics. Specifically, the cured film according to the present invention can be advantageously used as a material for a planarization film for a thin film transistor (TFT) substrate of a liquid crystal display or an organic EL display; a partition of an organic EL display; an interlayer dielectric of a semiconductor device; or an optical waveguide. Further, the cured film according to the present invention may be applied as a protective film in electronic components.

### MODE FOR THE INVENTION

Hereinafter, the present invention will be described in more detail with reference to the following examples. However, these examples are provided to illustrate the present invention, and the scope of the present invention is not limited thereto only.

In the following synthesis examples, the weight average molecular weight is determined by gel permeation chromatography (GPC, eluent: tetrahydrofuran) referenced to a polystyrene standard.

### [Synthesis Example 1] Preparation of a Siloxane Copolymer (A-1)

A reactor equipped with a reflux condenser was charged with 36% by weight of phenyltrimethoxysilane, 13% by weight of methyltrimethoxysilane, 21% by weight of tetraethoxysilane, 5% by weight of 1,2-bistrimethoxysilylethane, 20% by weight of distilled water, and 5% by weight of propylene glycol monomethyl ether acetate (PGMEA), followed by refluxing and vigorously stirring the mixture for 6 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-1). The siloxane copolymer thus prepared was subjected to GPC analysis, and its weight average molecular weight referenced to a polystyrene standard was confirmed to be 6,000 to 9,000 Da.

### [Synthesis Example 2] Preparation of a Siloxane Copolymer (A-2)

A reactor equipped with a reflux condenser was charged with 36% by weight of phenyltrimethoxysilane, 13% by weight of methyltrimethoxysilane, 21% by weight of tetraethoxysilane, 5% by weight of 1,2-bistrimethoxysilylethane, 20% by weight of distilled water, and 5% by weight of propylene glycol monomethyl ether acetate (PGMEA), followed by refluxing and vigorously stirring the mixture for 5 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-2). The siloxane copolymer thus prepared was subjected to GPC analysis, and its weight average molecular weight referenced to a polystyrene standard was confirmed to be 6,000 to 9,000 Da.

### [Synthesis Example 3] Preparation of a Siloxane Copolymer (A-3)

A reactor equipped with a reflux condenser was charged with 36% by weight of phenyltrimethoxysilane, 13% by weight of methyltrimethoxysilane, 21% by weight of tetraethoxysilane, 5% by weight of 2-(3,4-epoxycyclohexyl)ethyltrimethoxysilane, 20% by weight of distilled water, and 5% by weight of propylene glycol monomethyl ether acetate (PGMEA), followed by refluxing and vigorously stirring the mixture for 6 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-3). The siloxane copolymer thus prepared was subjected to GPC analysis, and its weight average molecular weight referenced to a polystyrene standard was confirmed to be 6,000 to 9,000 Da.

### [Synthesis Example 4] Preparation of a Siloxane Copolymer (A-4)

A reactor equipped with a reflux condenser was charged with 33% by weight of phenyltrimethoxysilane, 20% by weight of methyltrimethoxysilane, 22% by weight of tetraethoxysilane, 20% by weight of distilled water, and 5% by weight of propylene glycol monomethyl ether acetate (PGMEA), followed by refluxing and vigorously stirring the mixture for 6 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-4). The siloxane copolymer thus prepared was subjected to GPC analysis, and its weight average molecular weight referenced to a polystyrene standard was confirmed to be 6,000 to 9,000 Da.

### [Synthesis Example 5] Preparation of a Siloxane Copolymer (A-5)

A reactor equipped with a reflux condenser was charged with 40% by weight of phenyltrimethoxysilane, 14% by weight of methyltrimethoxysilane, 21% by weight of tetraethoxysilane, 20% by weight of distilled water, and 5% by weight of propylene glycol monomethyl ether acetate (PGMEA), followed by refluxing and vigorously stirring the mixture for 8 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-5). The siloxane copolymer thus prepared was subjected to GPC analysis, and its weight average molecular weight referenced to a polystyrene standard was confirmed to be 6,000 to 9,000 Da.

### [Synthesis Example 6] Preparation of a Siloxane Copolymer (A-6)

A reactor equipped with a reflux condenser was charged with 40% by weight of phenyltrimethoxysilane, 14% by weight of methyltrimethoxysilane, 21% by weight of tetraethoxysilane, 20% by weight of distilled water, and 5% by weight of propylene glycol monomethyl ether acetate (PGMEA), followed by refluxing and vigorously stirring the mixture for 6 hours in the presence of 0.1% by weight of an oxalic acid catalyst. Thereafter, it was cooled, diluted with PGMEA to adjust the solids content to 41% by weight, and aged in a freezer at 0° C. or lower for 24 hours to prepare a siloxane copolymer (A-6). The siloxane copolymer thus prepared was subjected to GPC analysis, and its weight average molecular weight referenced to a polystyrene standard was confirmed to be 6,000 to 9,000 Da.

### Test Example 1

The siloxane copolymers prepared in the Synthesis Examples were each applied onto a silicon wafer and pre-baked at 100° C. to form a pre-baked film having a thickness of 1 μm. Next, the pre-baked film thus formed was measured for the dissolution rate in an aqueous solution of 1.5% by weight of tetramethylammonium hydroxide (TMAH). The results are shown in Table 1 below.

### Test Example 2

85% by weight of each of the siloxane copolymers prepared in the Synthesis Examples and 15% by weight of a 1,2-quinonediazide compound (TPA523, Miwon) were mixed to prepare a mixture. Next, the mixture thus prepared was applied onto a silicon wafer and pre-baked at 100° C. to form a pre-baked film having a thickness of 1 μm. Next, the pre-baked film thus formed was measured for the dissolution rate in an aqueous solution of 1.5% by weight of tetramethylammonium hydroxide. The results are shown in Table 1 below.

TABLE 1

| | | | | | | | | | ADR of | ADR of |
|---|---|---|---|---|---|---|---|---|---|---|
| | | | | | | | | RT | Test Ex. 1 | Test Ex. 2 |
| | PTMS | MTMS | TES | BTMSE | ECHETES | DW | PGMEA | (hr) | (Å/sec) | (Å/sec) |
| Syn. Ex. | 36 | 13 | 21 | 5 | 0 | 20 | 5 | 6 | 2,800 | 0 |
| 1 (A-1) | | | | | | | | | | (insoluble) |
| Syn. Ex. | 36 | 13 | 21 | 5 | 0 | 20 | 5 | 5 | 3,200 | 0 |
| 2 (A-2) | | | | | | | | | | (insoluble) |
| Syn. Ex. | 36 | 13 | 21 | 0 | 5 | 20 | 5 | 6 | 2,900 | 0 |
| 3 (A-3) | | | | | | | | | | (insoluble) |
| Syn. Ex. | 33 | 20 | 22 | 0 | 0 | 20 | 5 | 6 | 2,900 | 578 |
| 4 (A-4) | | | | | | | | | | |
| Syn. Ex. | 40 | 14 | 21 | 0 | 0 | 20 | 5 | 8 | 850 | 0 |
| 5 (A-5) | | | | | | | | | | (insoluble) |
| Syn. Ex. | 40 | 14 | 21 | 0 | 0 | 20 | 5 | 6 | 3,400 | 1,934 |
| 6 (A-6) | | | | | | | | | | |

PTMS: penyltrimethoxysilane;
MTMS: mthyltrimethoxysilane;
TES: tetraethoxysilane;
BTMSE: 1,2-bis(trimethoxysilyl)ethane;
ECHETES: 2-(3,4-epoxycyclohexyl)ethyltrimethoxysilane;
DW: distilled water;
RT: reaction time

Referring to Table 1, in Synthesis Examples 1 to 3 in which a siloxane copolymer having a bridge structure introduced to its molecule by using 1,2-bistrimethoxysilylethane or 2-(3,4-epoxycyclohexyl)ethyltrimethoxysilane was pre-baked, the dissolution rate in an aqueous solution of 1.5% by weight of tetramethylammonium hydroxide was 2,500 Å/sec or more. When mixed with a 1,2-quinonediazide compound and pre-baked, it was insoluble in an aqueous solution of 1.5% by weight of tetramethylammonium hydroxide. In contrast, in Synthesis Examples 4 to 6 in which a siloxane copolymer without a bridge structure introduced to its molecule was pre-baked, the dissolution rate in an aqueous solution of 1.5% by weight of tetramethylammonium hydroxide was less than 2,500 Å/sec. When mixed with a 1,2-quinonediazide compound and pre-baked, it was soluble in an aqueous solution of 1.5% by weight of tetramethylammonium hydroxide.

### [Synthesis Example 7] Preparation of an Acrylic Copolymer (D-1)

A flask equipped with a cooling tube and a stirrer was charged with 200 parts by weight of propylene glycol monomethyl ether acetate (PGMEA) relative to 100 parts by weight of the reaction monomers, and the temperature of PGMEA was raised to 70° C. while it was stirred slowly. Next, added thereto were 19.8% by weight of styrene, 13.9% by weight of methyl methacrylate, 27.0% by weight of glycidyl methacrylate, 27.6% by weight of methacrylic acid, and 11.7% by weight of methyl acrylate. Subsequently, 3 parts by weight of 2,2′-azobis(2,4-dimethylvaleronitrile) as a radical polymerization initiator relative to 100 parts by weight of the reaction monomers was added thereto dropwise over 5 hours to carry out a polymerization reaction to prepare an acrylic copolymer (D-1) having a solids content of 32% by weight. The acrylic copolymer thus prepared was subjected to GPC analysis, and its weight average molecular weight referenced to a polystyrene standard was confirmed to be 9,000 to 11,000 Da.

### [Synthesis Example 8] Preparation of an Acrylic Copolymer (D-2)

A flask equipped with a cooling tube and a stirrer was charged with 200 parts by weight of propylene glycol monomethyl ether acetate (PGMEA) relative to 100 parts by weight of the reaction monomers, and the temperature of PGMEA was raised to 70° C. while it was stirred slowly. Next, added thereto were 19.8% by weight of styrene, 15.6% by weight of methyl methacrylate, 27.1% by weight of glycidyl methacrylate, 25.7% by weight of methacrylic acid, and 11.7% by weight of methyl acrylate. Subsequently, 3 parts by weight of 2,2′-azobis(2,4-dimethylvaleronitrile) as a radical polymerization initiator relative to 100 parts by weight of the reaction monomers was added thereto dropwise over 5 hours to carry out a polymerization reaction to prepare an acrylic copolymer (D-2) having a solids content of 32% by weight. The acrylic copolymer thus prepared was subjected to GPC analysis, and its weight average molecular weight referenced to a polystyrene standard was confirmed to be 9,000 to 11,000 Da.

### [Synthesis Example 9] Preparation of an Epoxy Compound (E-1)

A three-necked flask was equipped with a cooling tube and placed on a stirrer equipped with a thermostat. The flask was charged with 100 parts by weight of a monomer composed of 100% by mole of 3,4-epoxycyclohexylmethylmethacrylate, 10 parts by weight of 2,2′-azobis(2-methylbutyronitrile), and 100 parts by weight of propylene glycol monomethyl ether acetate (PGMEA), followed by charging nitrogen thereto. Thereafter, the temperature of the solution was raised to 80° C. while it was stirred slowly, and the temperature was maintained for 5 hours to carry out a synthesis reaction. It was diluted with PGMEA to obtain an epoxy compound (E-1) having a solids content of 21% by weight. The epoxy compound thus prepared was subjected to GPC analysis, and its weight average molecular weight referenced to a polystyrene standard was confirmed to be 5,000 to 8,000 Da.

### [Synthesis Example 10] Preparation of an Epoxy Compound (E-2)

A three-necked flask was equipped with a cooling tube and placed on a stirrer equipped with a thermostat. The flask was charged with 100 parts by weight of a monomer composed of 100% by mole of glycidyl methacrylate, 10 parts by weight of 2,2′-azobis(2-methylbutyronitrile), and 100 parts by weight of propylene glycol monomethyl ether acetate (PGMEA), followed by charging nitrogen thereto. Thereafter, the temperature of the solution was raised to 80° C. while it was stirred slowly, and the temperature was maintained for 5 hours to carry out a synthesis reaction. It was diluted with PGMEA to obtain an epoxy compound (E-2) having a solids content of 21% by weight. The epoxy compound thus prepared was subjected to GPC analysis, and its weight average molecular weight referenced to a polystyrene standard was confirmed to be 8,000 to 10,000 Da.

### [Example 1] Preparation of a Photosensitive Resin Composition

A reactor was charged with 26.2% by weight of the acrylic copolymer (A-1) of Synthesis Example 1 based on the total weight of the photosensitive resin composition excluding the solvents in a balanced amount. In addition, 47.8 parts by weight of a 1,2-quinonediazide compound (B-1), 50.0 parts by weight of the acrylic copolymer (D-1) of Synthesis Example 7, 173.3 parts by weight of the acrylic copolymer (D-2) of Synthesis Example 8, 10.0 parts by weight of the epoxy compound (E-1) of Synthesis Example 9, and 1.09 parts by weight of the surfactant (F) were added relative to 100 parts by weight of the siloxane copolymer (on the basis of the solids content). Then, a solvent (C) was added such that the solids content was 22% by weight based on the total weight of the photosensitive resin composition, which was dissolved for 3 hours. It was filtered through a membrane filter having a pore diameter of 0.2 μm to obtain a photosensitive resin composition having a solids content of 22% by weight.

### [Examples 2 to 4] Preparation of a Photosensitive Resin Composition

A photosensitive resin composition was prepared in the same manner as in Example 1, except that its composition was changed shown in Tables 2 and 3.

### [Comparative Examples 1 to 4] Preparation of a Photosensitive Resin Composition

A photosensitive resin composition was prepared in the same manner as in Example 1, except that its composition was changed shown in Tables 2 and 3.

TABLE 2

| | | | | | | | 1,2-Quinonediazide | |
|---|---|---|---|---|---|---|---|---|
| | | | | | | | compound (B) | |
| | | | | | | | B-1 | B-2 |
| | Siloxane copolymer (A) | | | | | | (TPA-523, | (TPA-517, |
| | A-1 | A-2 | A-3 | A-4 | A-5 | A-6 | Miwon) | Miwon) |
| Ex. 1 | 26.2 | — | — | — | — | — | 47.8 | — |
| Ex. 2 | — | 26.2 | — | — | — | — | 47.8 | — |
| Ex. 3 | 39.5 | — | — | — | 39.5 | — | — | 15.2 |
| Ex. 4 | — | — | 39.5 | — | 39.5 | — | — | 15.2 |
| C. Ex. 1 | — | — | — | 26.2 | — | — | 47.8 | — |
| C. Ex. 2 | — | — | — | 39.5 | 39.5 | — | — | 15.2 |
| C. Ex. 3 | — | — | — | — | 26.2 | — | 47.8 | — |
| C. Ex. 4 | — | — | — | — | — | 26.2 | 47.8 | — |

TABLE 3

| | | Acrylic | | | | |
|---|---|---|---|---|---|---|
| | Solvent | copolymer | | Epoxy | | Surfactant (G) |
| | (C) | (D) | | compound (E) | | FZ-2122, Dow |
| | PGMEA | D-1 | D-2 | E-1 | E-2 | Corning Toray |
| Ex. 1 | 78 | 50.0 | 173.3 | 10.0 | — | 1.09 |
| Ex. 2 | 78 | 50.0 | 173.3 | 10.0 | — | 1.09 |
| Ex. 3 | 78 | — | — | — | 11.1 | 1.09 |
| Ex. 4 | 78 | — | — | — | 11.1 | 1.09 |
| C. Ex. 1 | 78 | 50.0 | 173.3 | 10.0 | — | 1.09 |
| C. Ex. 2 | 78 | — | — | — | 11.1 | 1.09 |
| C. Ex. 3 | 78 | 50.0 | 173.3 | 10.0 | — | 1.09 |
| C. Ex. 4 | 78 | 50.0 | 173.3 | 10.0 | — | 1.09 |

### [Test Example 3] Evaluation of Development Loss

The photosensitive resin compositions prepared in the Examples and Comparative Examples were each coated onto a glass substrate by spin coating. It was then pre-baked on a hot plate kept at 100° C. for 180 seconds to form a dried film. The dried film thus formed was exposed to light through a mask having a pattern of square holes in a size ranging from 1 to 30 μm and through an i-line optical filter at an exposure dose of 0 to 300 mJ/cm² based on a wavelength of 365 nm for a certain time period using an aligner (model name: MA6) that emits light having a wavelength of 200 nm to 450 nm with a gap of 20 μm between the mask and the substrate. Next, it was developed with an aqueous developer of 2.38% by weight of tetramethylammonium hydroxide through puddle nozzles at 23° C. for 85 seconds. Next, it was exposed to light at an exposure dose of 200 mJ/cm² based on 365 nm for a certain time period using an aligner (model name: MA6) that emits light having a wavelength of 200 nm to 450 nm (i.e., bleaching step) and then heated in a convection oven at 240° C. for 20 minutes to prepare a cured film having a thickness of 3.5 μm.

In the course of forming the cured film, the thickness of the film obtained after pre-bake and the thickness of the film obtained after development were measured with a film thickness evaluation device (SNU Precision) to measure the development loss. The results are shown in Table 4 below.

Development loss=(film thickness after pre-bake)−(film thickness after development)

The smaller the measured value of development loss (Å), the more excellent. It is preferably 7,500 Å or less.

### [Test Example 4] Evaluation of Film Retention Rate

The photosensitive resin compositions prepared in the Examples and Comparative Examples were each coated onto a glass substrate by spin coating. It was then pre-baked on a hot plate kept at 100° C. for 180 seconds to form a dried film. Next, it was developed with an aqueous developer of 2.38% by weight of tetramethylammonium hydroxide through puddle nozzles at 23° C. for 85 seconds. Next, it was exposed to light at an exposure dose of 200 mJ/cm² based on 365 nm for a certain time period using an aligner (model name: MA6) that emits light having a wavelength of 200 nm to 450 nm (i.e., bleaching step) and then heated (post-baked) in a convection oven at 240° C. for 20 minutes to prepare a cured film having a thickness of 2.1 μm.

In the course of forming the cured film, the thickness of the film obtained after pre-bake and the thickness of the film obtained after post-bake were measured with a film thickness evaluation device (SNU Precision) to measure the film retention rate of the cured film. The results are shown in Table 4 below.

Film retention rate (%)=(film thickness after post-bake/film thickness after pre-bake)×100

The larger the measured value of film retention rate (%), the more excellent. It is preferably 70% or more.

### [Test Example 5] Evaluation of Surface Cloudiness

The photosensitive resin compositions prepared in the Examples and Comparative Examples were each coated onto a glass substrate by spin coating. It was then pre-baked on a hot plate kept at 100° C. for 180 seconds to form a dried film. The dried film thus formed was exposed to light through a mask having a pattern of square holes in a size ranging from 1 to 30 μm and through an i-line optical filter at an exposure dose of 0 to 200 mJ/cm² based on a wavelength of 365 nm for a certain time period using an aligner (model name: MA6) that emits light having a wavelength of 200 nm to 450 nm with a gap of 20 μm between the mask and the substrate. Next, it was developed with an aqueous developer of 2.38% by weight of tetramethylammonium hydroxide through puddle nozzles at 23° C. for 85 seconds. The surface of the film formed by the above process was visually observed to evaluate whether the surface was cloudy. The results are shown in Table 4 below.

If no surface cloudiness, it was evaluated as “x.” If slight surface cloudiness, it was evaluated as “o.” If severe surface cloudiness, it was evaluated as “⊚.”

TABLE 4

| | Development loss | Film retention | Surface |
|---|---|---|---|
| | (Å) | rate (%) | cloudiness |
| Ex. 1 | 7,145 | 71% | X |
| Ex. 2 | 5,852 | 75% | X |
| Ex. 3 | 1,100 | 92% | X |
| Ex. 4 | 6,700 | 74% | X |
| C. Ex. 1 | 9,100 | 65% | ◯ |
| C. Ex. 2 | 8,900 | 67% | ⊚ |
| C. Ex. 3 | 4,828 | 80% | ◯ |
| C. Ex. 4 | 20,259 | 50% | ◯ |

Referring to Table 4, in Examples 1 to 4 in which the photosensitive resin composition comprised a siloxane copolymer, which had a dissolution rate of 2,500 Å/sec or more in an aqueous solution of 1.5% by weight of tetramethylammonium hydroxide when the siloxane copolymer was pre-baked, and which was insoluble in an aqueous solution of 1.5% by weight of tetramethylammonium hydroxide when mixed with a 1,2-quinonediazide compound and pre-baked, the film retention rate was excellent, the development loss was small, and the cloudiness on the surface of the cured film after development was not observed as compared with Comparative Examples 1 to 4.

1. A positive-type photosensitive resin composition, which comprises:
(A) a siloxane copolymer;
(B) 1,2-quinonediazide compound; and
(C) a solvent,
wherein the siloxane copolymer, when pre-baked, has a dissolution rate of 2,500 Å/second or more in an aqueous solution of 1.5% by weight of tetramethylammonium hydroxide, and
when a mixture in which the siloxane copolymer and the 1,2-quinonediazide compound are mixed at a content of the 1,2-quinonediazide compound (B) of 15% by weight is pre-baked, it is insoluble in an aqueous solution of 1.5% by weight of tetramethylammonium hydroxide.

2. The positive-type photosensitive resin composition of claim 1, wherein the siloxane copolymer (A) comprises a phenyl group in an amount of 10 to 60% by mole based on the total number of moles of Si atoms.

3. The positive-type photosensitive resin composition of claim 1, wherein the amount of the siloxane copolymer (A) is 10% by weight to 95% by weight based on the total weight of the photosensitive resin composition excluding the balanced amount of solvents.

4. The positive-type photosensitive resin composition of claim 1, wherein the positive-type photosensitive resin composition further comprises (D) an acrylic copolymer.

5. The positive-type photosensitive resin composition of claim 1, wherein the positive-type photosensitive resin composition further comprises (E) an epoxy compound.

6. A positive-type photosensitive resin composition, which comprises:
(A) a siloxane copolymer;
(B) 1,2-quinonediazide compound; and
(C) a solvent,
wherein the siloxane copolymer (A) comprises a structural unit (a-1) derived from a silane compound (a₁) represented by the following Formula 1 or 2:
(R¹O)₃Si-L-Si(OR²)₃ [Formula 1]
R³Si(OR⁴)₃ [Formula 2]
in Formulae 1 and 2,
L is a single bond, oxygen, a substituted or unsubstituted C₁ to C₁₅ alkylene group, a substituted or unsubstituted C₃ to C₁₅ cycloalkylene group, a substituted or unsubstituted C₆ to C₁₅ arylene group, a substituted or unsubstituted 6- to 15-membered heteroarylene group, a substituted or unsubstituted C₂ to C₁₅ alkenylene group, or a substituted or unsubstituted C₂ to C₁₅ alkynylene group,
R¹, R², and R⁴ are each independently a substituted or unsubstituted C₁ to C₆ alkyl group, a substituted or unsubstituted C₁ to C₆ acyl group, or a substituted or unsubstituted C₆ to C₁₅ aryl group,
R³ is a C₁ to C₆ alkyl group substituted with a C₂ to C₁₅ cyclic ether group, and
the heteroarylene group has one or more heteroatoms selected from the group consisting of N, O, and S.

7. The positive-type photosensitive resin composition of claim 6, wherein the cyclic ether group is an epoxy group or a C₃ to C₁₀ cycloalkyl group containing an epoxy structure.

8. The positive-type photosensitive resin composition of claim 6, wherein L is a C₂ to C₆ alkylene group, R¹, R², and R⁴ are each independently a C₁ to C₄ alkyl group, and R³ is a C₁ to C₄ alkyl group substituted with a C₄ to C₈ cyclic ether group.

9. The positive-type photosensitive resin composition of claim 6, wherein the siloxane copolymer (A) comprises the structural unit (a-1) in an amount of 1 to 50% by mole based on the total number of moles of Si atoms.

10. The positive-type photosensitive resin composition of claim 6, wherein the siloxane copolymer (A) further comprises a structural unit (a-2) derived from a silane compound (a2) represented by the following Formula 3:
(R⁷)ₙSi(OR⁸)₄₋ₙ [Formula 3]
in Formula 3,
n is an integer of 0 to 3,
R⁷ is each independently C₁ to C₁₂ alkyl, C₂ to C₁₀ alkenyl, C₆ to C₁₅ aryl, 3- to 12-membered heteroalkyl, 4- to 10-membered heteroalkenyl, or 6- to 15-membered heteroaryl,
R⁸ is each independently hydrogen, C₁ to C₆ alkyl, C₂ to C₆ acyl, or C₆ to C₁₅ aryl, and
the heteroalkyl, the heteroalkenyl, and the heteroaryl groups each independently have at least one heteroatom selected from the group consisting of 0, N, and S.

11. The positive-type photosensitive resin composition of claim 10, wherein the structural unit (a-2) is derived from three or more types of the silane compound (a2) represented by Formula 3.

12. The positive-type photosensitive resin composition of claim 10, wherein the siloxane polymer (A) comprises a structural unit derived from the silane compound of Formula 3 where n is 0 in an amount of 5 to 60% by mole based on the total number of moles of Si atoms.

13. A cured film prepared from the positive-type photosensitive resin composition according to claim 1.
